(19) United States
(12) Patent Application Publication
(10) Pub. No.: US 2025/0192748 A1
(43) Pub. Date: Jun. 12, 2025

(54) MEMBRANE-TYPE LONGITUDINAL MODE RESONATOR

(71) Applicant: RF360 Singapore Pte. Ltd., Republic Plaza (SG)

(72) Inventors: Soeren ZIMMERMANN, München (DE); Benno BLASCHKE, Munich (DE); Jan Philip KRING, München (DE)

(21) Appl. No.: 18/535,925

(22) Filed: Dec. 11, 2023

(51) Int. Cl. H03H 9/02; H03H 3/08; H03H 9/25

(52) U.S. Cl. CPC H03H 9/02834; H03H 3/08; H03H 9/02559; H03H 9/02574; H03H 9/02866; H03H 9/25

(57) ABSTRACT

Methods, apparatuses, and other aspects are disclosed for microacoustic resonators. In one aspect, an apparatus includes a temperature compensation layer comprising a first surface and a second surface opposite the first surface, and a piezoelectric layer having a first surface and a second surface opposite the first surface, where the piezoelectric layer is disposed on the first surface of the temperature compensation layer with the second surface of the piezoelectric layer facing the first surface of the temperature compensation layer, and where the piezoelectric layer has an orientation configured to excite a longitudinal mode. The apparatus further includes an electrode structure comprising an interdigital transducer disposed on the first surface of the piezoelectric layer, where the second surface of the temperature compensation layer faces an air gap.

### TECHNICAL FIELD

This disclosure relates generally to microacoustic resonators for electronic signal filters and, more specifically, to membrane-type longitudinal mode microacoustic resonators.

### BACKGROUND

Electronic devices include traditional computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system).

Wireless communication transceivers used in these electronic devices generally include multiple radio frequency (RF) filters for filtering a signal for a particular frequency or range of frequencies. Microacoustic devices (e.g., “acoustic filters”) are used for filtering high-frequency (e.g., generally greater than 100 MHz) signals in many applications. Using a piezoelectric material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as the electronic devices enumerated above (e.g., particularly including portable electronic devices such as cellular phones).

### SUMMARY

An apparatus is disclosed that implements a microacoustic resonator in a membrane-type longitudinal mode implementation.

In one aspect, an apparatus is provided. The apparatus comprises a dielectric layer comprising a first surface and a second surface opposite the first surface; a piezoelectric layer having a first surface and a second surface opposite the first surface, wherein the piezoelectric layer is disposed on the first surface of the dielectric layer with the second surface of the piezoelectric layer facing the first surface of the dielectric layer, and wherein the piezoelectric layer is LiNbO3 having a crystallographic orientation defined by a set of Euler angles of λ=90+/−1.5°, μ=90+/−1.5°, θ=40+/−1.5°; and an electrode structure comprising an interdigital transducer disposed on the first surface of the piezoelectric layer, wherein the second surface of the dielectric layer faces an air gap.

In some aspects, the air gap is formed in a bulk substrate where edges of the air gap are aligned with a border of an active region of the electrode structure. Some aspects further comprise a protection layer having a first surface facing the bulk substrate and the air gap, and a second surface opposite the first surface, wherein the second surface faces the dielectric layer. Some such aspects further comprise a dielectric cover layer disposed on the piezoelectric layer; a passivation layer disposed on the dielectric cover layer.

Another aspect is a method of fabricating a microacoustic resonator. The method comprises providing a piezoelectric wafer or layer having a first surface and a second surface opposite the first surface wherein the piezoelectric wafer or layer has an orientation configured to excite a longitudinal mode in the microacoustic resonator; depositing a temperature compensation layer on the first surface of the piezoelectric layer; structuring a sacrificial layer on the temperature compensation layer; depositing an intermediate layer over the sacrificial layer and the temperature compensation layer; bonding a bulk substrate on the intermediate layer; grinding and polishing the second surface the piezoelectric layer to a target thickness for the piezoelectric layer; fabricating an interdigital transducer on the second surface of the piezoelectric layer; forming a passivation layer over the interdigital transducer and the second surface of the piezoelectric layer; etching a release hole through the passivation layer, the piezoelectric wafer or layer, and the temperature compensation layer to the sacrificial layer; and release etching the sacrificial layer to form an air gap against the temperature compensation layer opposite the interdigital transducer.

Another aspect is a method comprising providing a piezoelectric layer having a first surface and a second surface opposite the first surface, wherein the piezoelectric layer has an orientation configured to excite a longitudinal mode in a microacoustic resonator and configured to suppress a shear horizontal mode; depositing a temperature compensation layer on the first surface of the piezoelectric layer; forming a first passivation layer on the temperature compensation layer; bonding a bulk substrate on the first passivation layer; grinding and polishing the second surface of the piezoelectric layer to a target thickness for the piezoelectric layer; fabricating an interdigital transducer on the second surface of the piezoelectric layer; forming a second passivation layer over the interdigital transducer and the second surface of the piezoelectric layer; and forming an air gap through the bulk substrate to the first passivation layer in an area opposite the interdigital transducer.

Another aspect is an apparatus. The apparatus comprises a temperature compensation layer comprising a first surface and a second surface opposite the first surface; a piezoelectric layer having a first surface and a second surface opposite the first surface, wherein the piezoelectric layer is disposed on the first surface of the temperature compensation layer with the second surface of the piezoelectric layer facing the first surface of the temperature compensation layer, and wherein the piezoelectric layer has an orientation configured to excite a longitudinal mode; an electrode structure comprising an interdigital transducer disposed on the first surface of the piezoelectric layer; wherein the second surface of the temperature compensation layer faces an air gap.

Some aspects are configured where the piezoelectric layer comprises LiNbO3 with a crystallographic orientation defined by a set of Euler angles of approximately (λ=90°, μ=90°, θ=40°); and wherein the orientation to excite the longitudinal mode and suppresses a shear horizontal mode comprises a Euler angle orientation of λ=90+/−1.5°, μ=90+/−1.5°, θ=40+/−1.5°.

Some aspects further comprise a protection layer formed between the temperature compensation layer and the air gap. Some such aspects are configured where the protection layer comprises a Al₂O₃ layer having a first surface facing the temperature compensation layer, and a second surface exposed to the air gap.

Some aspects further comprise an intermediate layer disposed on the temperature compensation layer. Some aspects are configured where the air gap is formed within the intermediate layer using a sacrificial layer. Some aspects are configured where the intermediate layer comprises a SiO2 layer. Some aspects are configured where further comprising a bulk substrate bonded to the intermediate layer, the bulk substrate comprising silicon. Some aspects are configured where the temperature compensation layer is an SiOF layer directly adjacent to the air gap.

Some aspects are configured where the SiOF layer has a thickness of approximately 100 nanometers (nm). In some aspects, the SiOF layer has a thickness between 95 nm and 105 nm.

Some such aspects further comprise a passivation layer formed over the electrode structure and the first surface of the piezoelectric layer. Some aspects are configured where the passivation layer comprises an Si3N4 layer.

Some aspects further comprise a dielectric cover formed over the electrode structure and the first surface of the piezoelectric layer. Some aspects are configured where the dielectric cover comprises an SiO2 layer. Some aspects further comprise a passivation layer disposed on the dielectric cover; wherein the dielectric cover and the passivation layer are configured to suppress a low velocity Rayleigh mode.

Some aspects further comprise a bulk substrate attached to the temperature compensation layer via a protective layer. Some aspects are configured where the air gap is formed via Bosch fabrication of the air gap through the bulk substrate to the protective layer opposite the electrode structure.

Some aspects are configured where the air gap is formed within a bulk substrate supporting the temperature compensation layer; and wherein a boundary of an active region is aligned with edges of the interdigital transducer and edges of the air gap.

Some aspects further comprise a protection layer disposed between the bulk substrate and the temperature compensation layer.

Some aspects are configured where the microacoustic resonator is disposed in a wireless communication filter for a communication frequency between 2.5 gigahertz (GHz) and 6 GHz.

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The foregoing, together with other features and embodiments, will become more apparent upon referring to the following specification, claims, and accompanying drawings.

### BRIEF DESCRIPTION OF DRAWINGS

FIG. 1 illustrates an example operating environment for a surface-acoustic-wave (SAW) resonator in accordance with aspects described herein.

FIG. 2 illustrates an example wireless transceiver including filters implemented with SAW resonators in accordance with aspects described herein.

FIG. 3 illustrates aspects of a SAW device in accordance with aspects described herein.

FIGS. 4A and 4B illustrate an example implementation of a SAW resonator in accordance with aspects described herein.

FIG. 5 illustrates example Euler angles that define an orientation of a crystalline structure of a piezoelectric material in a SAW resonator in accordance with aspects described herein.

FIG. 6A illustrates aspects of a membrane-type longitudinal mode resonator device in accordance with aspects described herein.

FIG. 6B illustrates resonance response charts of a membrane-type resonator at a number of different Euler angles.

FIG. 6C illustrates resonance response charts of a membrane-type resonator at a selected Euler angle cut in accordance with aspects described herein.

FIG. 6D illustrates charts including multiple response curves as a thickness of the membrane is varied, showing suppression of the Rayleigh modes in accordance with some aspects described herein.

FIG. 6E illustrates charts with a resonator simulated at a selected Euler angle and a selected membrane thickness in accordance with aspects described herein.

FIG. 7 illustrates aspects of a membrane-type longitudinal mode resonator device in accordance with aspects described herein.

FIG. 8 illustrates aspects of a membrane-type longitudinal mode resonator device in accordance with aspects described herein.

FIGS. 9A-H illustrate aspects of a fabrication of a membrane-type longitudinal mode resonator device in accordance with some aspects described herein.

FIG. 10 illustrates aspects of a membrane-type longitudinal mode resonator device in accordance with aspects described herein.

FIG. 11 illustrates aspects of a fabrication of a membrane-type longitudinal mode resonator device in accordance with some aspects described herein.

FIGS. 12A and 12B illustrate aspects of resonator use in a wireless communication apparatus in accordance with aspects described herein.

FIGS. 13A and 13B illustrate aspects of a resonator in accordance with certain implementations described herein.

FIGS. 14A and 14B are a flow diagrams illustrating example processes for fabricating a resonator in accordance with aspects described herein.

### DETAILED DESCRIPTION

The detailed description set forth below in connection with the appended drawings is intended as a description of example implementations and is not intended to represent the only implementations in which the invention may be practiced. The detailed description includes specific details for the purpose of describing aspects of surface-acoustic-wave (SAW) devices. Alternative aspects which are not specifically detailed are possible within the scope of the described aspects.

Microacoustic devices (e.g., “acoustic filters”) can be used to filter high-frequency (e.g., generally greater than 100 MHZ) signals in many applications. A microacoustic filter is tuned to pass certain frequencies (e.g., frequencies within its passband) and reject or reflect other frequencies (e.g., frequencies that are outside of its passband). Using a piezoelectric material as a vibrating medium, the acoustic filter operates by transforming an electrical signal wave that is propagating along an electrical conductor into an acoustic wave (e.g., an acoustic signal wave) that forms across the piezoelectric material. The acoustic wave is then converted back into an electrical filtered signal.

The acoustic wave propagates across the piezoelectric material at a velocity that is significantly less than that of the propagation velocity of the electrical wave. Generally, the propagation velocity v of a wave is proportional to the wavelength lambda of the wave and depends on its frequency f (e.g., where velocity v=lambda*f). Consequently, after conversion of the electrical signal wave into the acoustic wave, the wavelength of the acoustic wave is significantly smaller than the wavelength of the electrical signal wave. The resulting smaller wavelength of the acoustic wave enables filtering to be performed using a smaller filter device. This permits acoustic filters to be used in space-constrained devices, including portable electronic devices such as cellular phones.

Microacoustic resonators are designed to cause propagation of an acoustic wave in a particular direction through the piezoelectric material, and the resonators can be combined into filters that are used to manage communication signals. Performance demand challenges for microacoustic filters are associated with ever-increasing requirements for various filter characteristics, including higher communication frequencies, resonance quality factors, electromechanical coupling performance, temperature range performance, power durability, insertion loss, reduction of spurious modes, reduced costs, etc.

In particular, surface acoustic wave (SAW) modes of microacoustic resonators have performance issues at frequencies above approximately 3 gigahertz (GHz) due to the small finger electrode dimensions at these frequencies causing fabrication issues, and being associated with parasitic effects.

Aspects described herein include microacoustic resonators configured to operate by exciting high-velocity longitudinal surface acoustic wave modes (e.g., as opposed to lower velocity Rayleigh modes or shear horizontal modes). Such resonators involve trade-offs among relevant performance characteristics, and challenges with confining acoustic energy to the desired modes. Aspects described herein include membrane-type longitudinal mode resonators, where an air gap area is used opposite an interdigital transducer (e.g., on an opposite side of a device stacking including at least a piezoelectric layer and a substrate).

Such an air gap can be combined with a particular Euler angle configuration of the piezoelectric layer (e.g., a piezoelectric layer such as lithium niobate with a well-defined crystal orientation specified by the Euler angle convention, where the Euler angles (λ, μ, θ) are set to approximately (λ=90°, μ=90°, θ=40°))) and/or a device configuration to select excitation of high-velocity longitudinal modes. In some aspects, the air gap can be fabricated within an internal layer of a substrate using an etched sacrificial layer with an etch release hole. In other aspects, a Bosch process can be used to fabricate a complete backside opening underneath resonators of a device (e.g., with the resonators on one side of a stack and an air gap through a substrate on the opposite side of a piezoelectric layer).

Various aspects of the present disclosure will be described with respect to the figures.

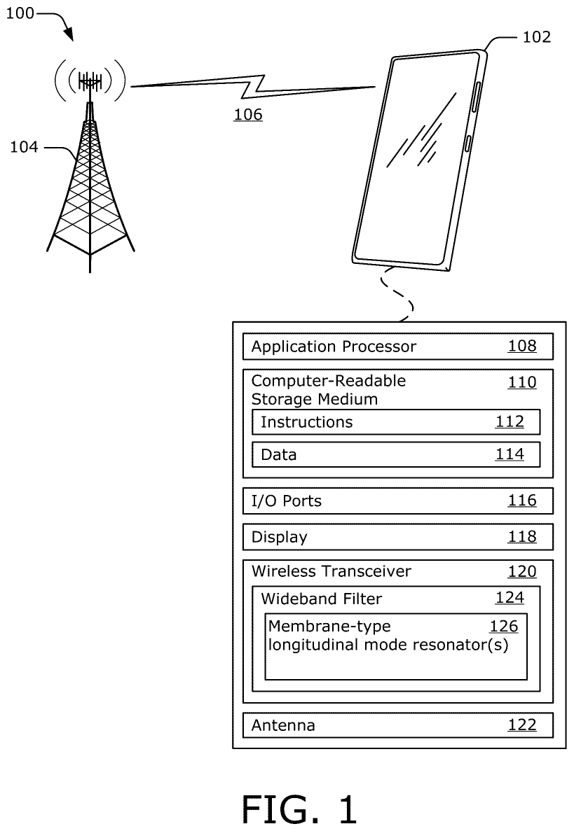

FIG. 1 illustrates an example environment 100 for wireless communications including devices that can be configured with membrane-type longitudinal mode resonators in accordance with aspects described herein. In the environment 100, a computing device 102 communicates with a base station 104 through a wireless communication link 106 (wireless link 106). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, a fiber optic line, and so forth. Therefore, the computing device 102 may communicate with the base station 104 or another device via a wired connection, a wireless connection, or a combination thereof.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), or 5th-generation (5G) cellular, IEEE 802.11 (e.g., Wi-Fi™), IEEE 802.15 (e.g., Bluetooth™), IEEE 802.16 (e.g., WiMAX™), and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, that executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface, through which graphical content of the computing device 102 is presented.

A wireless transceiver 120 of the computing device 102 provides connectivity to respective networks and other electronic devices connected therewith. Alternatively or additionally, the computing device 102 can include a wired transceiver, such as an Ethernet or fiber optic interface for communicating over a local network, intranet, or the Internet. The wireless transceiver 120 can facilitate communication over any suitable type of wireless network, such as a wireless local area network (WLAN), peer-to-peer (P2P) network, mesh network, cellular network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

In the example shown in FIG. 1, the wireless transceiver 120 includes at least one filter 124 having one or more membrane-type longitudinal mode resonators 126. In some aspects, such resonators 126 can be fabricated using methods described further below.

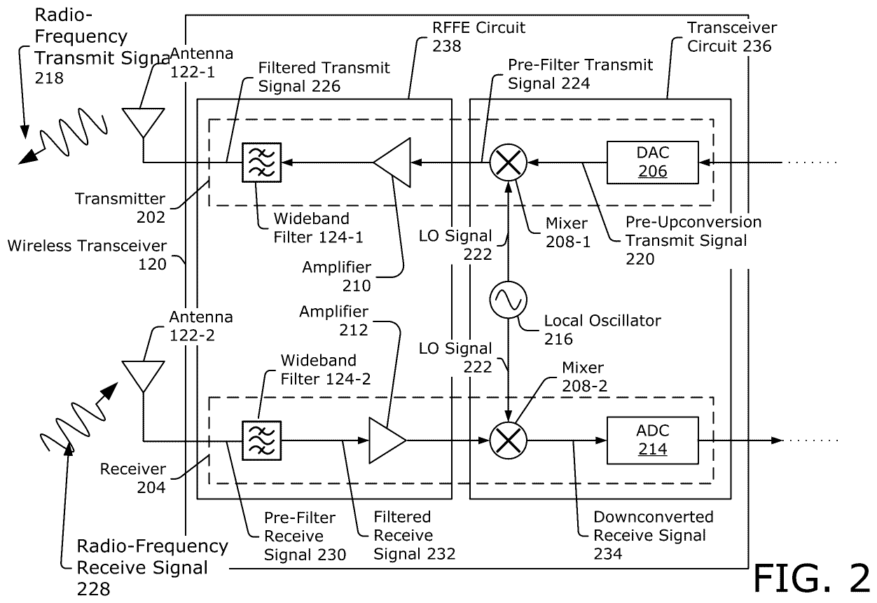

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be selectively connected to a same antenna through a switch (not shown). The transmitter 202 is shown to include at least one digital-to-analog converter 206 (DAC 206), at least one first mixer 208-1, at least one amplifier 210 (e.g., a power amplifier), and at least one first wideband filter 124-1. The receiver 204 includes at least one second wideband filter 124-2, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the digital-to-analog converter 206 of the transmitter 202 and the analog-to-digital converter 214 of the receiver 204 can be coupled to the application processor 108 (of FIG. 1) or another processor associated with the wireless transceiver 120 (e.g., a modem).

In some implementations, the wireless transceiver 120 is implemented using multiple circuits, such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the digital-to-analog converter 206 of the transmitter 202, the mixer 208-1 of the transmitter 202, the mixer 208-2 of the receiver 204, and the analog-to-digital converter 214 of the receiver 204. In other implementations, the digital-to-analog converter 206 and the analog-to-digital converter 214 can be implemented on another separate circuit that includes the application processor 108 or the modem. The radio-frequency front-end circuit 238 includes the amplifier 210 of the transmitter 202, the wideband filter 124-1 of the transmitter 202, the wideband filter 124-2 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the digital-to-analog converter 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, which is referred to as a pre-filter transmit signal 224. The pre-filter transmit signal 224 can be a radio-frequency signal and include some spurious (e.g., unwanted) frequencies, such as a harmonic frequency. The amplifier 210 amplifies the pre-filter transmit signal 224 and passes the amplified pre-filter transmit signal 224 to the wideband filter 124-1. The first wideband filter 124-1 filters the amplified pre-filter transmit signal 224 to generate a filtered transmit signal 226. As part of the filtering process, the first wideband filter 124-1 attenuates the one or more spurious frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The second wideband filter 124-2 accepts the received radio-frequency receive signal 228, which is represented by a pre-filter receive signal 230. The second wideband filter 124-2 filters any spurious frequencies within the pre-filter receive signal 230 to generate a filtered receive signal 232. Example spurious frequencies can include jammers or noise from the external environment. The amplifier 212 of the receiver 204 amplifies the filtered receive signal 232 and passes the amplified filtered receive signal 232 to the second mixer 208-2. The second mixer 208-2 downconverts the amplified filtered receive signal 232 using the local oscillator signal 222 to generate the downconverted receive signal 234. The analog-to-digital converter 214 converts the downconverted receive signal 234 into a digital signal, which can be processed by the application processor 108 or another processor associated with the wireless transceiver 120 (e.g., the modem). The wideband filters 124-1 and 124-2 can be implemented by one or more membrane-type longitudinal mode resonators 126.

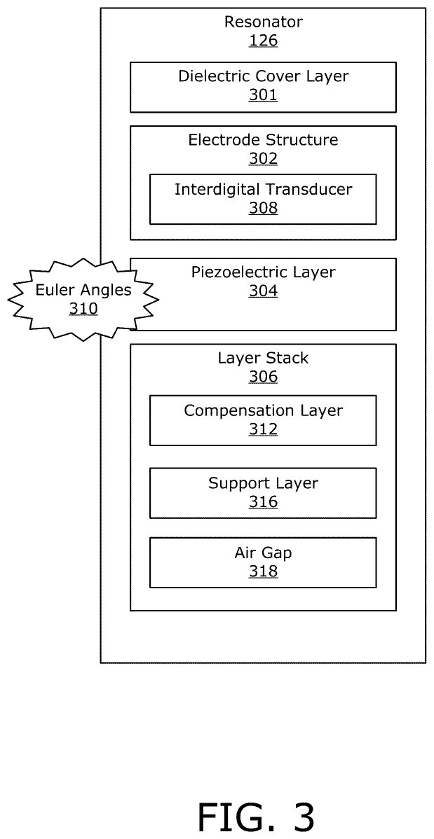

FIG. 3 illustrates example components of an acoustic-wave resonator 126. In the depicted configuration, the acoustic-wave resonator 126 includes a dielectric cover layer 301, at least one electrode structure 302, at least one piezoelectric layer 304 (e.g., piezoelectric material), and at least one layer in a layer stack 306. The electrode structure 302 comprises an electrically conductive material, such as metal or a semiconductor, and can include one or more layers. The one or more layers can include one or more metal and/or semiconductor layers and can optionally include one or more adhesion layers. As an example, the electrically conductive layers can be composed of aluminum (Al), copper (Cu), silver (Ag), gold (Au), tungsten (W), silicon (Si) or some combination or doped version thereof. The adhesion layers can be composed of chromium (Cr), titanium (Ti), molybdenum (Mo), or some combination thereof.

The electrode structure 302 includes one or more interdigital transducers 308. The interdigital transducer 308 converts an electrical signal into an acoustic wave and converts the acoustic wave into a filtered electrical signal. One interdigital transducer (IDT) converts an electric signal into an acoustic wave, and has a strong frequency dependent admittance so the IDT functions as a basic structure for filtering. Some filters work with a combination of two or more IDTs, where one IDT excites the wave, which is received and converted back by one other IDT. Other filters use two or more IDTs with reflector fingers, and may only use the combination of the frequency dependent admittances to filter the electrical signal. In some systems, there may be a combination of multiple kinds of filtering in one device. Thus, as described above, an IDT such as the interdigital transducer 308 converts an electrical signal into an acoustic wave and/or converts the acoustic wave back into an electrical signal.

An example interdigital transducer 308 is further described below. Although not explicitly shown, the electrode structure 302 can also include two or more reflectors. In an example implementation, the interdigital transducer 308 is arranged between two reflectors, which reflect the acoustic wave back towards the interdigital transducer 308.

The material of the piezoelectric layer 304 and the orientation of the propagation surface with respect to the crystal structure of the material affects several performance parameters. Example performance parameters include an electromechanical coupling factor (k), a temperature coefficient of frequency (TCF), resonance quality (Q) factor, a mode or type of acoustic wave produced, and/or a velocity of the acoustic wave. The electromechanical coupling factor characterizes an efficiency of the acoustic-wave resonator 126 in converting between electrical energy and mechanical energy. The temperature coefficient of frequency characterizes an amount a resonant frequency or filter skirt of the filter changes in response to a change in temperature. A filter with a smaller absolute value of the temperature coefficient of frequency has a more stable frequency response over a range of temperatures compared to another filter with a larger absolute value of the temperature coefficient of frequency. The Q factor characterizes losses associated with energy leakage relating it to the energy initially stored in the resonator. A resonator with a high Q factor has less losses than a resonator with a lower Q factor. The electromechanical coupling factor k² is related to the conversion rate between electrical energy and mechanical energy, and k² is a ratio of stored mechanical energy to input electrical energy.

The layer stack 306 can include one or more sublayers (e.g., including a substrate or carrier layer and other layers). Layers in the layer stack 306 can support charge trapping, temperature compensation, power handling, mode suppression, and so forth.

In some aspects, the layer stack 306 can include at least one compensation layer 312, at least one support layer 316, or some combination thereof. In other aspects, protection layers, bulk substrate layers, or an air gap 318 fabricated using a sacrificial sublayer within the layer stack 306 can be used. These sublayers can be considered part of the layer stack 306 or their own separate layers.

The compensation layer 312 can provide temperature compensation to enable the resonator 126 to achieve the target temperature coefficient of frequency based on the thickness of the material in the piezoelectric layer 304. In some implementations, a thickness of the compensation layer 312 can be tailored to provide mode suppression (e.g., suppress the spurious plate mode). In example implementations, the compensation layer 312 can be implemented as the layer stack 306. In other implementations, SiO₂, SiOF (e.g., Fluorine doped SiO₂), or SiOC (e.g., Carbon doped SiO₂) can be used as materials with intrinsically temperature compensating characteristics (e.g., stiffening under higher temperatures).

The support layer 316 can enable the acoustic wave to form across the surface of the piezoelectric layer 304 and reduce the amount of energy that leaks into the layer stack 306. In some implementations, the support layer 316 can also act as a compensation layer 312. In general, the support layer 316 is composed of material that is non-conducting and provides isolation. For example, the support layer 316 can include at least one silicon (Si) layer (e.g., a doped high-resistive silicon layer), at least one sapphire layer, at least one silicon carbide (SiC) layer, at least one fused silica layer, at least one glass layer, at least one diamond layer, or some combination thereof. In some implementations, the support layer 316 has a relatively similar thermal expansion coefficient (TEC) as the piezoelectric layer 304.

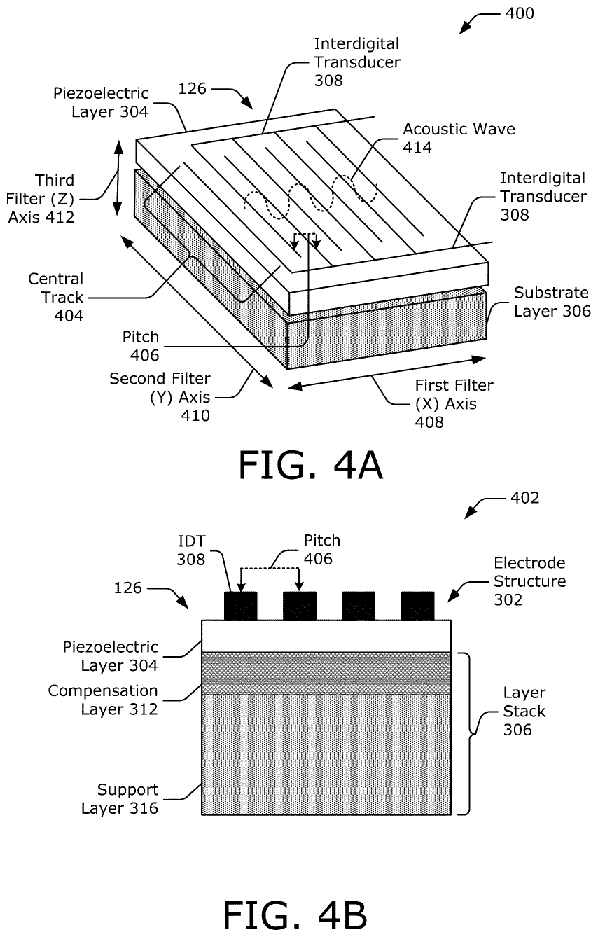

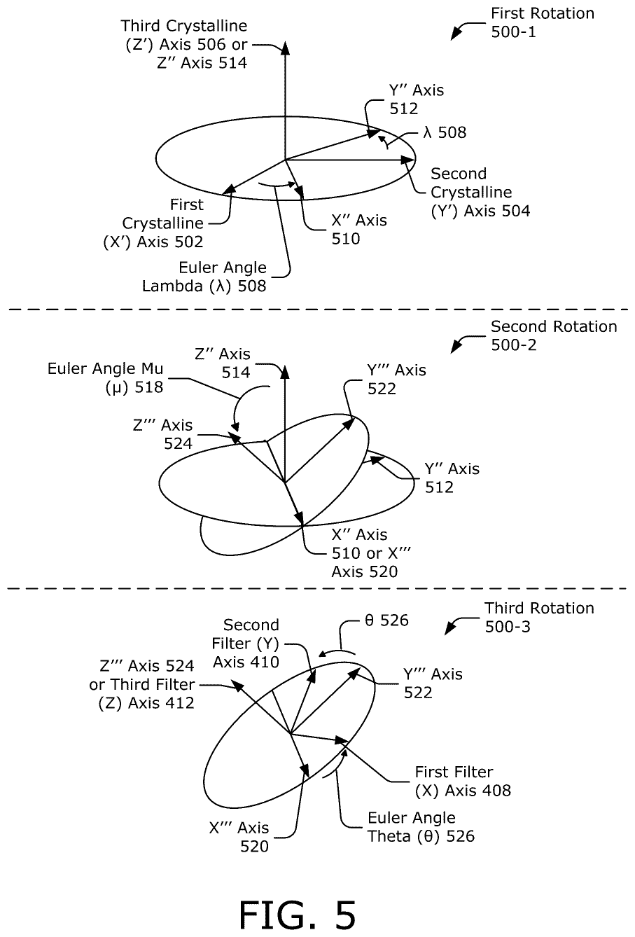

FIGS. 4A and 4B illustrate an example implementation of an example resonator (e.g., the resonator 126). A three-dimensional perspective view 400 of the resonator 126 is shown in FIG. 4A, and a two-dimensional cross-section view 402 of the resonator 126 is shown in FIG. 4B.

In the depicted configuration shown in the two-dimensional cross-section view 402, the piezoelectric layer 304 is disposed between the electrode structure 302 and the layer stack 306. FIG. 4A shows a single substrate layer, but in some implementations, the layer stack 306 can include sublayers as described above and below, such as the compensation layer 312, a protection layer, an intermediate support layer (e.g., for a sacrificial layer and an associated air gap), the support layer 316, or other such sub-layers of a substrate. Although not explicitly shown in FIGS. 4A and 4B, the electrode structure 302 can also include one or more other interdigital transducers 308 and two or more reflectors.

In the three-dimensional perspective view 400, the interdigital transducer 308 is shown to have two comb-shaped electrode structures with fingers extending from two busbars (e.g., conductive segments or rails) towards each other. The electrode fingers are arranged in an interlocking manner in between the two busbars of the interdigital transducer 308 (e.g., arranged in an interdigitated manner). In other words, the fingers connected to a first busbar extend towards a second busbar but do not connect to the second busbar. As such, there is a gap between the ends of these fingers and the second busbar. Likewise, fingers connected to the second busbar extend towards the first busbar but do not connect to the first busbar. There is therefore a gap between the ends of these fingers and the first busbar.

In the direction along the busbars, there is an overlap region including a central region 404 where a portion of one finger overlaps with a portion of an adjacent finger. This central region 404, including the overlap, may be referred to as the aperture, track, or active region where electric fields are produced between fingers to cause an acoustic wave 414 to form at least in this region of the piezoelectric layer 304.

A physical periodicity of the fingers is referred to as a pitch 406 of the interdigital transducer 308. The pitch 406 may be indicated in various ways. For example, in certain aspects, the pitch 406 may correspond to a magnitude of a distance between consecutive fingers of the interdigital transducer 308 in the central region 404. This distance may be defined, for example, as the distance between center points of each of the fingers. The distance may be generally measured between a right (or left) edge of one finger and the right (or left) edge of an adjacent finger when the fingers have uniform widths. In certain aspects, an average of distances between adjacent fingers of the interdigital transducer 308 may be used for the pitch 406.

The frequency at which the piezoelectric layer 304 vibrates is a main-resonance frequency of the stack including the electrode structure 302 of the resonator 126 (e.g., as illustrated in FIG. 4A from the perspective view 400, where the entire stack of the resonator 126 vibrates at a resonance from the surface down and into the substrate). The frequency is determined at least in part by the pitch 406 of the interdigital transducer 308 and other properties of the thin-film surface-acoustic-wave resonator 126. As an example, the pitch 406 can be approximately 0.5 micrometers (μm) to enable the resonator 126 to have a main-resonance frequency of approximately 5 GHz. Other pitches 406 are also possible to realize other main-resonance frequencies. In some aspects, aiming a high-velocity longitudinal mode goes along with a larger pitch at a certain frequency, when compared to a low velocity Rayleigh or shear horizontal (SH) mode. Both Rayleigh and SH modes are associated with much smaller pitches to target a same frequency. Such smaller pitches are associated with fabrication challenges and parasitic effects that can be reduced by using the high-velocity longitudinal mode.

It should be appreciated that while a certain number of fingers are illustrated in FIGS. 4A and 4B, the number of actual fingers and lengths and width of the fingers and busbars may be different in an actual implementation. Such parameters depend on the particular application and desired filter characteristics. In addition, the thin-film surface-acoustic-wave resonator 126 can include multiple interconnected electrode structures each including multiple interdigital transducers 308 to achieve a desired passband (e.g., multiple interconnected resonators or interdigital transducers 308 in series or parallel connections to form a desired filter transfer function).

Although not shown, each reflector within the electrode structure 302 can have two busbars and a grating structure of conductive fingers that each connect to both busbars. In some implementations, the pitch of the reflector can be similar to or the same as the pitch 406 of the interdigital transducer 308 to reflect the acoustic wave 414 in the resonant frequency range.

In the three-dimensional perspective view 400, the thin-film surface-acoustic-wave resonator 126 is defined by a first filter (X) axis 408, a second filter (Y) axis 410, and a third filter (Z) axis 412. The first filter axis 408 and the second filter axis 410 are parallel to a planar surface of the piezoelectric layer 304, and the second filter axis 410 is perpendicular to the first filter axis 408. The third filter axis 412 is normal (e.g., perpendicular) to the planar surface of the piezoelectric layer 304. The busbars of the interdigital transducer 308 are oriented to be parallel to the first filter axis 408. The fingers of the interdigital transducer 308 are orientated to be parallel to the second filter axis 410.

During operation, the resonator 126 accepts a radio-frequency signal, such as the pre-filter transmit signal 224 or the pre-filter receive signal 230 shown in FIG. 2. The electrode structure 302 excites an acoustic wave 414 on the piezoelectric layer 304 using the inverse piezoelectric effect. For example, the interdigital transducer 308 in the electrode structure 302 generates an alternating electric field based on the accepted radio-frequency signal. The piezoelectric layer 304 enables the acoustic wave 414 to be formed in response to the alternating electric field generated by the interdigital transducer 308. In other words, the piezoelectric layer 304 causes, at least partially, the acoustic wave 414 to form responsive to electrical stimulation by one or more interdigital transducers 308.

The acoustic wave 414 propagates across the piezoelectric layer 304 and interacts with the interdigital transducer 308 or another interdigital transducer within the electrode structure 302 (not shown in FIG. 4A or 4B). The acoustic wave 414 that propagates can be a standing wave. In some implementations, two reflectors within the electrode structure 302 cause the acoustic wave 414 to be formed as a standing wave across a portion of the piezoelectric layer 304. In other implementations, the acoustic wave 414 propagates across the piezoelectric layer 304 from the interdigital transducer 308 to another interdigital transducer.

Using the piezoelectric effect, the electrode structure 302 is used as described above to filter radio frequency signals associated with the propagated surface acoustic wave 414. In particular, the piezoelectric layer 304 generates an alternating electric field due to the mechanical stress generated by the propagation of the acoustic wave 414. The alternating electric field induces an alternating current in the other interdigital transducers (e.g., the interdigital transducer 308). The alternating current forms the filtered radio-frequency signal, which is provided at an output of the thin-film surface-acoustic-wave resonator 126. In some aspects, resonators can have multiple electric ports, or a single port with no input or output, but an admittance value. The filtered radio-frequency signal can include the filtered transmit signal 226 or the filtered receive signal 232 of FIG. 2.

FIG. 5 illustrates example Euler angles 310 (of FIG. 3) that define an orientation of the piezoelectric material crystalline structure in the piezoelectric layer 304 of the resonator 126. A first crystalline (X′) axis 502, a second crystalline (Y′) axis 504, and a third crystalline (Z′) axis 506 are fixed along crystallographic axes of a crystal (e.g., LT). A first rotation 500-1 is applied to rotate the first crystalline X′ axis 502 and the second crystalline Y′ axis 504 about the third crystalline Z′ axis 506. In particular, the first rotation 500-1 rotates the first crystalline X′ axis 502 in a direction of the second crystalline Y′ axis 504. The angle associated with the first rotation 500-1 characterizes one of the Euler angles 310, which is represented by Euler angle lambda (λ) 508. The resulting rotated axes are represented by a new set of axes: an X″ axis 510, a Y″ axis 512, and a Z″ axis 514. As shown in FIG. 5, the third crystalline Z′ axis 506 remains unchanged by the first rotation 500-1 such that the third crystalline Z′ axis 506 is equal to the Z″ axis 514.

In a second rotation 500-2, the Y″ axis 512 and the Z″ axis 514 are rotated about the X″ axis 510 by another Euler angle 310, which is represented by Euler angle mu (μ) 518. In this case, the Y″ axis 512 is rotated in the direction of the Z″ axis 514. The resulting rotated axes are represented by a new set of axes: an X′″ axis 520, a Y″′ axis 522, and a Z′″ axis 524. As shown in FIG. 5, the X″ axis 510 remains unchanged by the second rotation 500-2 such that the X″ axis 510 is equal to the X′″ axis 520.

In a third rotation 500-3, the X′″ axis 520 and the Y′″ 522 axis are rotated about the Z″′ axis 524 by an additional Euler angle 310, which is represented by Euler angle theta (θ) 526. In this case, the X″′ axis 520 is rotated in the direction of the Y″′ axis 522. The resulting rotated axes are represented by the filter axes of FIGS. 4A and 4B (e.g., the first filter X axis 408, the second filter Y axis 410, and the third filter Z axis 412). As shown in FIG. 5, the Z″′ axis 524 remains unchanged by the third rotation 500-3 such that the Z′″ axis 524 is equal to the third filter Z axis 412. The X axis 408 specifies the direction of formation of the acoustic wave 414.

In some aspects, a particular set of Euler angles can be configured in a device for targeted longitudinal mode operation with a membrane-type resonator. For example, in some aspects, a lithium niobate (LiNbO₃) piezoelectric layer with a set of Euler angles of approximately (λ=90°, μ=90°, θ=40°) (e.g., within plus or minus 1 degree on all angles) to excite longitudinal mode microacoustic waves with high electromechanical coupling. In general, a variation in any of the Euler angles 310 can be set by given manufacturing process tolerances, which in some aspects can be a variation less than or equal to +/−1.5°, and in other aspects, a variation in any of the Euler angles 310 is less than or equal to +/−0.2°. Therefore, the term approximately can mean that any of the Euler angles can be within +/−1.5° of a specified value or less (e.g., within +/−0.2° of a specified value, within +/−1° of a specified value, 90+/−1.5°, 90+/−1.5°, 40+/−1.5°, etc.). While a particular example of a structure to excite longitudinal modes has been described, it should be appreciated that other materials that may similarly excite longitudinal modes as described may also be used. For example, in some aspects, Euler angles of (λ=0°, μ=−50°, θ=50°), can be used within variations of +/−1.5° for each angle. In other aspects, Euler angles of (λ=0°, μ=80°, θ=90°) can be used within approximate variations of +/−1.5° for each angle. In other aspects, other sets of Euler angles can be used or other variations or tolerances can be used within a set of Euler angles.

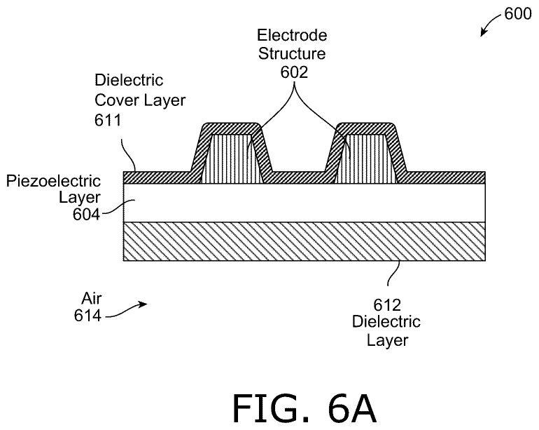

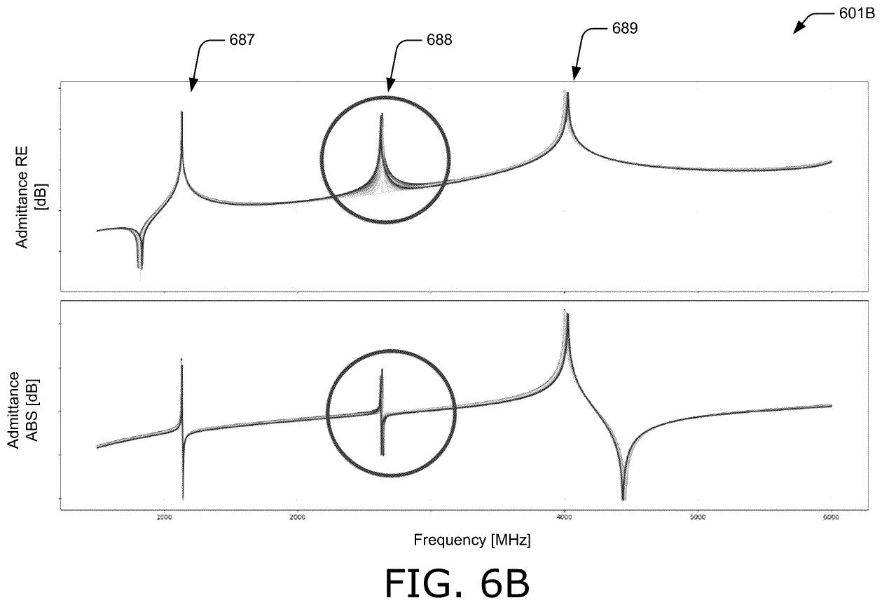

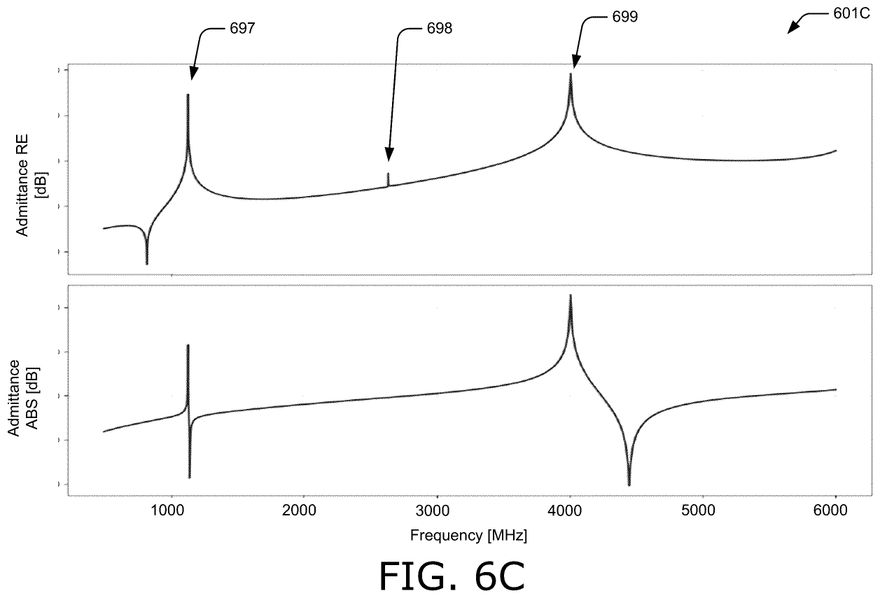

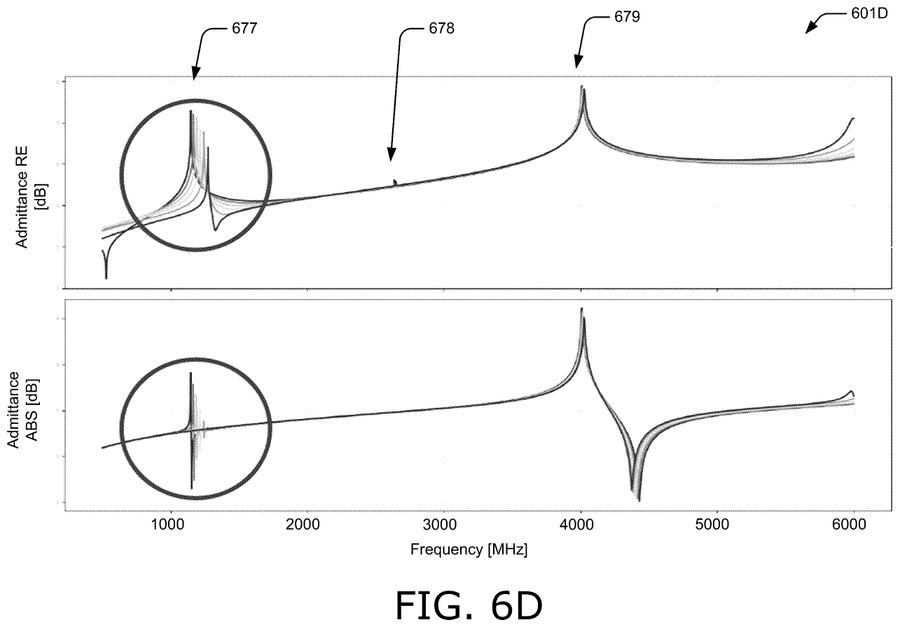

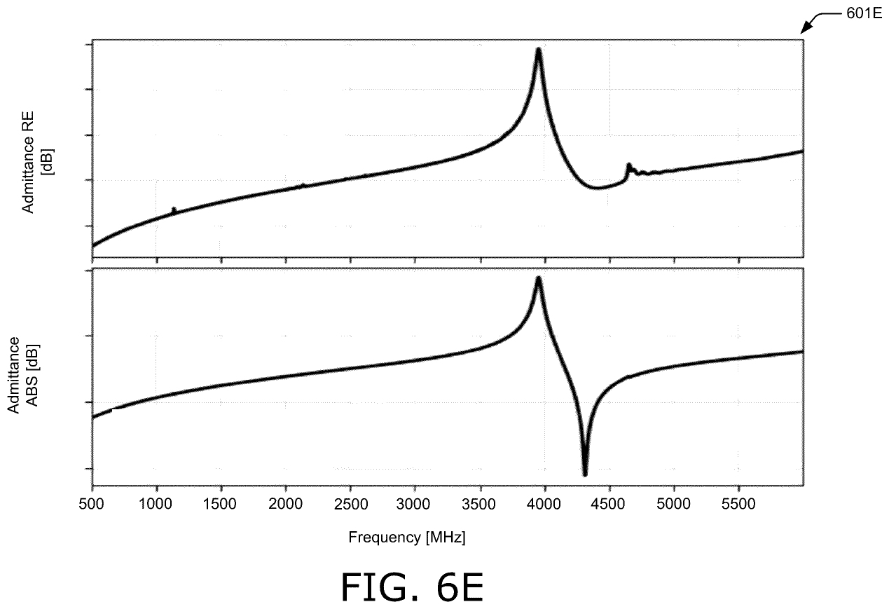

FIG. 6A illustrates aspects of a membrane-type longitudinal mode resonator 600 in accordance with aspects described herein. The resonator 600 includes an illustrated multilayer stack, with a piezoelectric layer 604 (e.g., lithium niobate) disposed on (e.g., in contact with or touching) a dielectric layer 612 (e.g., SiOF)). As discussed above, the dielectric layer 612 can comprise a single material, or multiple materials in different sub-layers (not shown in FIG. 6A). The resonator 600 includes an optional dielectric cover layer 611 disposed over the electrode structure and the top surface of the piezoelectric layer 604. In some aspects, the dielectric cover layer 611 can be formed using a single material, or can include multiple materials formed in different sublayers. Below the substrate layer on the opposite side from the electrode structure 602 is an air gap 614. The air gap can be positioned opposite the electrode structure 602 (e.g., on the other size of the piezoelectric layer 604 and the dielectric layer 612) to create the membrane structure referred to herein as a membrane-type structure of a resonator as illustrated by the resonator 600. As illustrated, the dielectric layer faces the air gap, such that a membrane-type structure is formed between the air gap 614 and the electrode structure 602, with a bottom surface of the membrane (e.g., a bottom portion of the dielectric layer 612, or a sublayer of the dielectric layer 612 exposed to the air gap 614).

Outside supporting areas adjacent to the air gap 614 and/or below the air gap 614 and not shown in FIG. 6A provide physical support for the other layers as illustrated below.

The resonator 600 can be configured in a variety of ways with the illustrated piezoelectric stack for longitudinal mode operation. Other longitudinal mode stacks can include a LiNbO₃ piezoelectric layer with different orientation stacked on SiO₂, polysilicon, and a carrier, or a dielectric acoustic mirror layer configuration (e.g., a dielectric sandwiched between two SiO₂ layers on polysilicon and a carrier) with (λ0°, μ=80°, θ=90°), (λ=90°, μ=90°, θ=45°), or (λ=0°, μ=−50°, θ=50°) Euler angle sets for the orientation of the LiNbO₃ piezoelectric layer. Such longitudinal mode stacks, however, can suffer from mode leakage issues and high insertion loss at bulk wave onsets associated with deteriorating Q factors. Some of these issues can be addressed in the membrane-type configuration illustrated by the resonator 600.

In particular, the resonator 600 is configured as a suspended multilayer stack with no significant carrier below the dielectric layer 612. As such, acoustic modes can be limited, with little or no energy in acoustic modes associated with the air cavity below the substrate layer, in turn leading to improved confinement of the acoustic energy (e.g., unlike the leaky longitudinal mode stacks described above). By configuring the dielectric layer 612 as a thin temperature compensation layer (TCL) comprising SiO₂, or C-doped SiO₂, or F-doped SiO₂, temperature coefficient of frequency of the membrane-type longitudinal mode resonator can be adjusted to be close to zero.

The resonator 600 of FIG. 6A further comprises an electrode structure 602 disposed on a surface of the piezoelectric layer opposite the dielectric layer 612. The electrode structure can be any acceptable metallization layer, such as Aluminum based metallization layers. In one aspect, the electrode structure is an approximately 70 nanometer (nm) layer of a multilayer metal stack comprising Ti, Cu, and Al layers. In some aspects, the dielectric cover layer 611 can be a SiO₂ layer with a thickness of approximately 50 nm. In some aspects, the dielectric cover layer 611 can be included for suppression of low-frequency modes as needed for performance in some design implementations.

FIG. 6B illustrates a simulated admittance 601B of a membrane-type resonator at a number of different Euler angles (λ=90°, μ=90°, θ) of LiNbO₃, with the θ angle varied over from θ=35° to θ=45° in steps of 1°. The simulation is obtained from finite element simulation. The simulated performances illustrated in FIGS. 6B-6E are examples provided for purposes of illustrating performance associated with aspects described herein. In illustrated charts, the horizontal axis is a frequency axis in megahertz (MHz) from below 1000 MHz (e.g., 1 gigahertz (GHz)) to above 6000 MHZ (e.g., 6 GHZ). The vertical axis shows absolute (Abs) and real (Re) part admittance values in decibels (dB). As illustrated, for the Euler angle cuts (λ=90°, μ=90°, θ), with 35°≤θ≤45°, three major resonance peaks occur, shown as peaks 687, peaks 688, and peaks 689. The lower frequency peaks 687 are peaks associated with the low velocity Rayleigh modes, the peaks 688 are associated with the shear horizontal modes, and the peaks 689 are associated with the desired high-velocity longitudinal modes. Varying the angle θ can suppress the resonance associated with the shear horizontal modes, with a minimum occurring around θ=40° degrees, as illustrated in FIG. 6C.

FIG. 6C illustrates simulated admittance charts 601C of a membrane-type resonator at a selected set of Euler angles (λ=90°, μ=90°, θ=40°) of LiNbO₃, in accordance with aspects described herein. Similar to the charts of FIG. 6B above, FIG. 6C similarly illustrates peaks 697, 698, and 699 corresponding to the Rayleigh modes, the shear horizontal modes, and the longitudinal modes correspondingly. As seen by the significant reduction in the peaks 698 compared to the peaks 688, the selected set of Euler angles at (λ=90°, μ=90°, θ=40°) of LiNbO₃ in a membrane-type resonator configuration largely suppresses the resonance of the shear horizontal modes, allowing a cleaner admittance required for various filter designs. While the Rayleigh modes associated with the peaks 697, 697 are not suppressed, a dielectric cover layer can be used to suppress these modes as described above and below (e.g., the dielectric cover layer 611).

FIG. 6D illustrates charts 601D illustrating multiple simulated admittance curves as a thickness of the silicon dioxide layer in the dielectric cover layer 611 is varied, showing peaks 677, 678, and 679 corresponding to the peaks of FIGS. 6B and 6C, and showing suppression of the Rayleigh modes associated with the peaks 687, 697. As illustrated, the peaks are suppressed by a SiO2 dielectric cover of thickness 50 nm or greater, with an increasing impact at frequencies near 6 GHz as the thickness is increased, resulting in an acceptable response curve around approximately 50 nm of SiO2 thickness. Thus, as illustrated in the charts showing the simulated admittances 601B, C, and D, by combining a suppression 50 nm SiO2 layer in the dielectric cover with a set of Euler angles (λ=90°, μ=90°, θ=40°) of LiNbO₃, longitudinal modes can be emphasized while largely suppressing the lower velocity modes that result in negative performance impacts for a membrane-type longitudinal mode resonator.

FIG. 6E then shows charts 601E with the resonator 600 simulated with the set of Euler angles (λ=90°, μ=90°, θ=40°) of LiNbO₃ and the 50 nm SiO2 dielectric cover. The simulated admittance shows performance for a resonator having a 150 nm thick LiNbO₃ piezoelectric layer with a set of Euler angles (λ=90°, μ=90°, θ=40°), a 100 nm thick SiOF TCL substrate layer over an air gap, a 50 nm thick SiO₂ dielectric cover, and a 80 nm thick Al based metallization layer with a finger pitch of 650 nm and a metallization ratio of 0.5. Such a design can result in improved resonator and filter devices, with spurious mode suppression, near-zero temperature coefficient of frequency, a high antiresonance Q value (e.g., approximately 500 as indicated above) and a high k² value (e.g., approximately 19%, where: k²=(π²/4)*(fr/fa)*((fa−fr)/fr), where fr is the resonance frequency and fa is the antiresonance frequency). This combination is desired for various bands in the frequency ranges up to approximately 7 GHZ (e.g., communication frequencies between 2.5 GHZ and 6 GHz, or other similar frequency bands).

Adjustments to the various design aspects (e.g., layer thickness, resonator pitch, etc.) can be used to target performance for given applications, along with possible variations, including, but not limited to, variations described below.

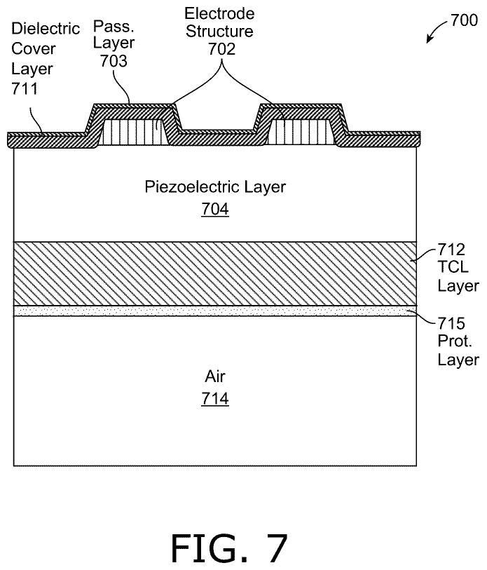

FIG. 7 illustrates additional aspects of a membrane-type longitudinal mode resonator 700 device in accordance with aspects described herein. The resonator 700 includes a similar structure as the resonator 600 of FIG. 6A, with a piezoelectric layer 704 disposed on a thin temperature compensation layer (TCL) 712 implemented. An electrode structure 702 is disposed on the piezoelectric layer 704 (e.g., illustrated as cross section cuts of the fingers of an interdigital transducer), with a Rayleigh mode suppressing dielectric cover layer 711 formed over the electrode structure 702 and the top of the piezoelectric layer 704.

The resonator 700 additionally includes a passivation layer 703 formed over the dielectric cover layer 711, and a protection layer 715 formed between the TCL layer 712 and the air gap 714. In some aspects, the passivation layer 703 can be a silicon nitride (Si₃N₄) layer, which can be approximately 5 nm. In some aspects, the dielectric cover layer 711 can be a suitable dielectric material for suppressing low-velocity modes (e.g., Rayleigh modes). In some aspects, this dielectric cover layer 711 can be a 50 nm SiO₂ layer. In some aspects, the piezoelectric layer 704 can be a 150 nm thick layer of LiNbO₃ with a crystal orientation specified by the set of Euler angles (λ=90°, μ=90°, θ=40°). In some aspects, the temperature compensation layer can be a 100 nm SiOF layer (e.g., F-doped SiO₂). In some aspects, the protection layer can be a 5 nm Al₂O₃ layer. The example thicknesses described above are approximate for the described example. In other implementations, other thicknesses can be used for performance in a given application in accordance with aspects described herein.

In some aspects, the passivation layer 703 can be included without the dielectric cover layer 711. The passivation layer 703 protects the piezoelectric layer 704 and the electrode structure 702 from environmental impacts on performance. The protection layer 715 can similarly protect the TCL substrate layer 712 from environmental impacts (e.g., due to variations in gas in the air gap 714, etc.)

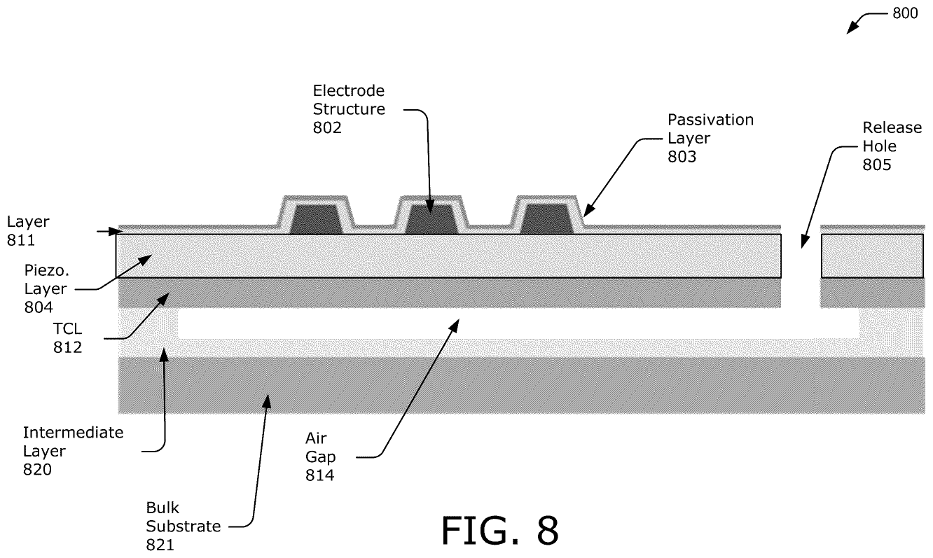

FIG. 8 illustrates additional aspects of a membrane-type longitudinal mode resonator 800 in accordance with aspects described herein. The resonator 800 of FIG. 8 includes an electrode structure 802, a passivation layer 803, and a dielectric cover layer 811 formed over a piezoelectric layer 804, with the piezoelectric layer 804 disposed on a temperature compensation layer 812, which is formed over an air gap 814, similar to the configuration of the resonator 600 of FIG. 6A. The resonator 800 illustrates the additional supporting substrates used to support the device including the resonator 800, shown as an intermediate layer 820 attached to a bulk substrate 821. The air gap 814 is formed inside the intermediate layer 820 via a release hole 805. In some aspects, multiple release holes or other geometries can be used (e.g., including different geometries for a single device, or any combination of structures to perform the function of a release hole). In some aspects a release hole cap, or plug (not shown) can be formed over the release hole 805 after the air gap 814 is fabricated to seal and enclose the air gap 814, and prevent environmental contamination of the air gap 814.

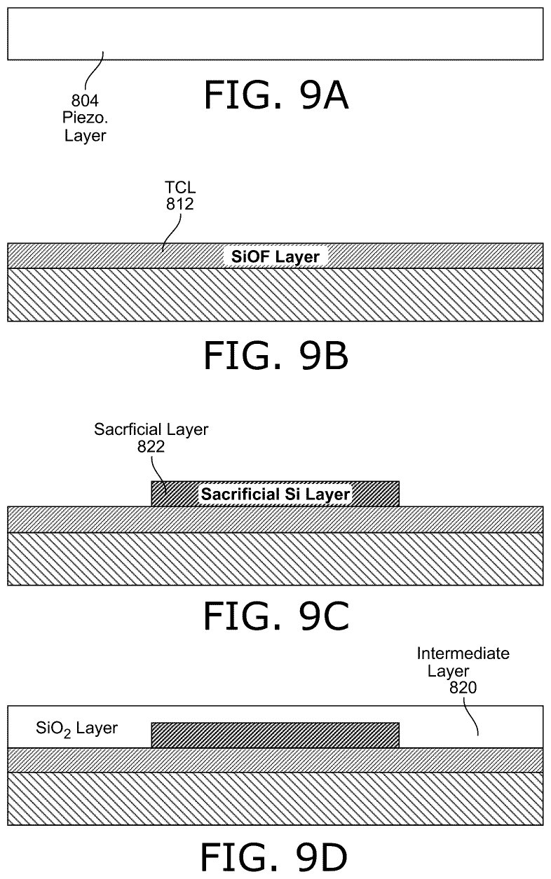

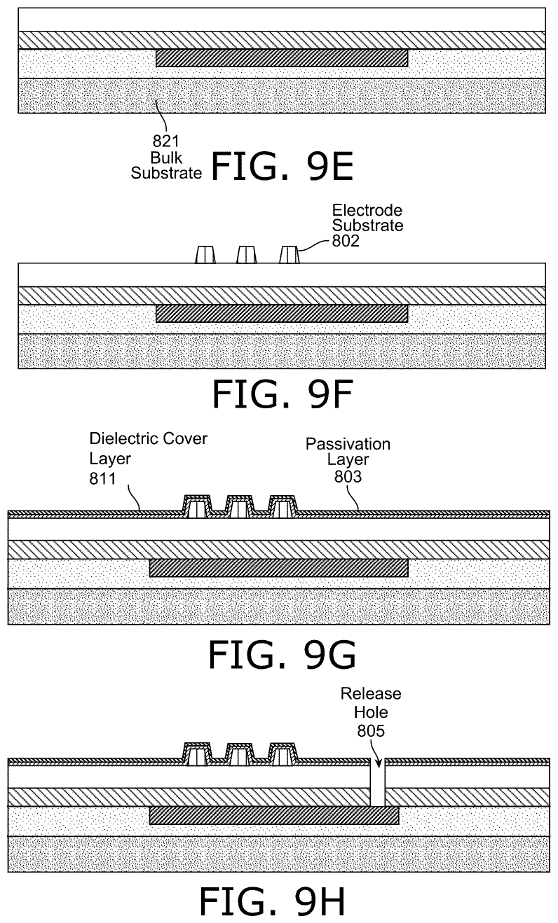

FIGS. 9A-H illustrate aspects of a fabrication of the membrane-type longitudinal mode resonator 800 in accordance with some aspects described herein. In FIG. 9A, the piezoelectric layer 804 is provided as a wafer with a selected set of Euler angles (e.g., (λ=90°, μ=90°, θ=40°) as described above). The piezoelectric layer forming the piezoelectric layer 804 has a first surface and a second surface opposite the first surface. In FIG. 9B, a temperature compensation layer 812 is deposited on the first surface of the piezoelectric layer 804. In FIG. 9C, a sacrificial layer 822 that will be used to create the air gap 814 is formed. In FIG. 9D the intermediate layer 820 is formed (e.g., SiO₂). In FIG. 9E, a bulk silicon wafer (e.g., a crystalline wafer) is bonded to the intermediate layer 820 to form the bulk substrate 821 (e.g., with the illustrated perspective shifting to flip the orientation between FIG. 9D and FIG. 9E). The piezoelectric layer 804 can be adjusted by grinding and/or polishing the piezoelectric layer 804 to a target thickness for a given design and performance. Then, in FIG. 9F, the electrode structure 802 is formed on the piezoelectric layer to form an interdigital transducer and other elements of a resonator on the piezoelectric layer. In FIG. 9G, the dielectric cover layer 811 and the passivation layer 803 are formed. In FIG. 9H a release hole 805 is etched through the dielectric cover layer 811, the passivation layer 803, the piezoelectric layer 804, and the temperature compensation layer 812 to the sacrificial layer 822. The sacrificial layer 822 can then be release etched (e.g., via XeF₂ etching) to form the air gap 814, resulting in the structure of the resonator 800 of FIG. 8.

In some aspects, after deposition of the TCL 812, a first etch stop layer can be formed. In some aspects, lithography, etching, and/or resist stripping can be used to structure the sacrificial layer 822 such that the air gap 814 will be positioned opposite the electrode structure 802, while allowing the intermediate layer 820 to form supporting structures in other areas. In some aspects, an SiOF adhesion layer can be fabricated on the intermediate layer 820 to assist with the bonding of the bulk substrate 821.

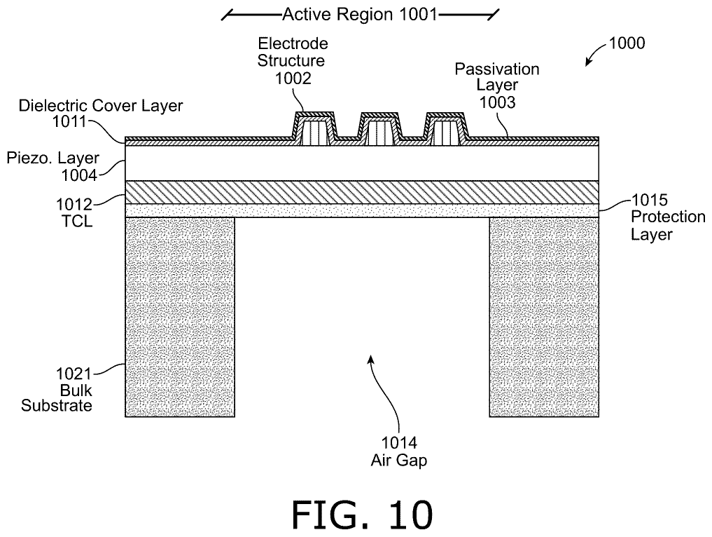

FIG. 10 illustrates aspects of another membrane-type longitudinal mode resonator 1000 in accordance with aspects described herein. Similar to the resonators described above, the resonator 1000 includes a piezoelectric layer 1004 formed on a TCL 1012, with an electrode structure 1002 disposed on the piezoelectric layer and covered by a dielectric cover layer 1011 and a passivation layer 1003.

The resonator 1000 includes a protection layer 1015 over a side of the TCL 1012 opposite the electrode structure 1002 (e.g., on an opposite side of the piezoelectric layer 1004 and the TCL 1012 from the electrode structure 1002) between the TCL 1012 and the air gap 1014. In contrast to the resonator 800, the resonator 1000 has an air gap 1014 open through the back of a bulk substrate 1021, with the bulk substrate 1021 acting as the support for the portions of the resonator 1000 outside of the electrode structure area (e.g., the membrane structure of the membrane-type resonator).

In some aspects, the air gap 1014 can be aligned with the interdigital transducers of the electrode structure 1002 to form an active region 1001 where microacoustic activity is focused within a device as described above. The alignment can be along a boundary at borders of the active region 1001 where edges of the active fingers of an interdigital transducer approximately align with walls in a substrate (e.g., a bulk substrate) around the air gap 1014. In other aspects, the air gap 1014 can have any other alignment to support a given device structure or performance in accordance with aspects described herein.

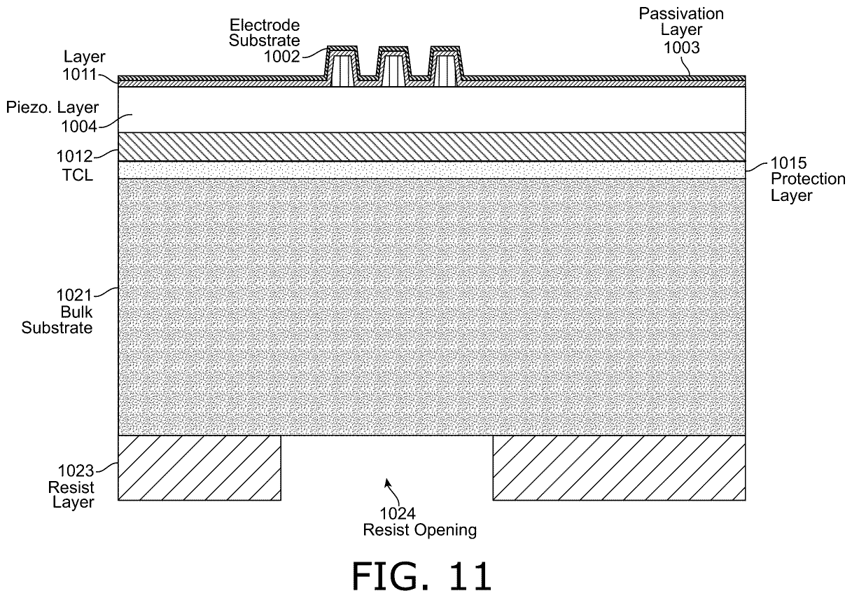

FIG. 11 illustrates aspects of a fabrication of the membrane-type longitudinal mode resonator 1000 in accordance with some aspects described herein. FIG. 11 shows the bulk substrate 1021 before etching, with a resist layer 1023 formed over the bulk substrate 1021. A resist opening 1024 is present for etching of the air gap 1014 through the bulk substrate 1021 to the protection layer 1015. In some aspects, the air gap 1014 area is formed using a Bosch process to form a complete backside opening opposite the interdigital transducers of the electrode structure 1002. As described above, trimming and tuning operations can be used during fabrication to tune performance aspects of the resonator 1000.

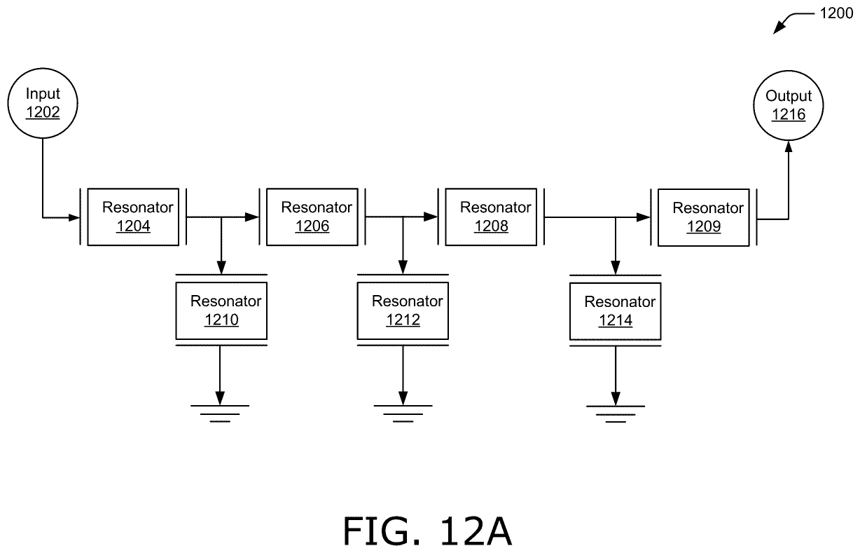

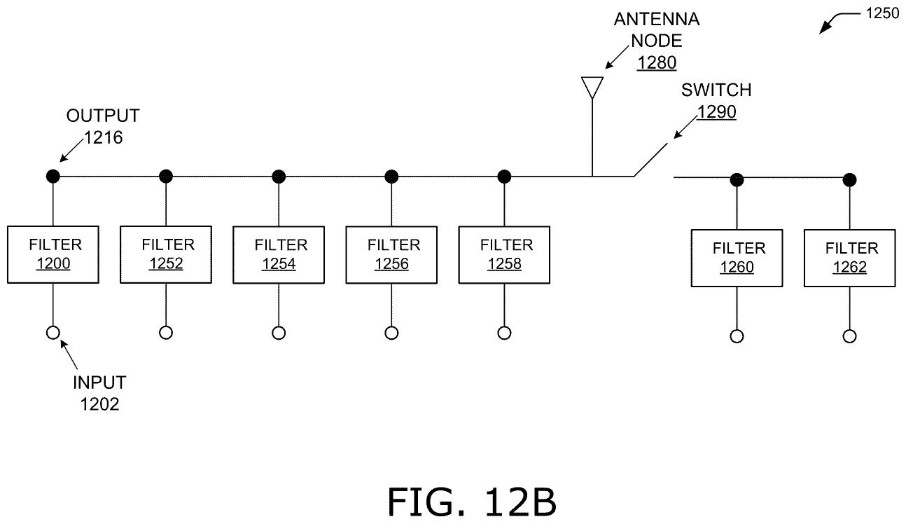

FIG. 12A is a schematic diagram of a microacoustic filter circuit 1200 that includes one or more membrane-type longitudinal mode resonators in accordance with aspects described herein (e.g., to implement a filter for a wireless communication signal). The example of FIG. 12A includes a ladder type structure. In other examples, other structures can be used. The filter circuit 1200 provides one example of where a resonator in accordance with aspects described herein can provide performance improvements as described above. The filter circuit 1200 includes an input 1202 and an output 1216. Between the input 1202 and the output 1216 a ladder network of resonators is provided. The resonators can be membrane-type longitudinal mode resonators or any other such resonator device (e.g., surface acoustic wave resonators, bulk acoustic wave resonators, etc.), including at least one membrane-type longitudinal mode resonator in accordance with aspects described herein. The filter circuit 1200 includes a first resonator 1204, a second resonator 1206, a third resonator 1208, and a fourth resonator 1209 all electrically connected in series between the input 1202 and the output 1216. A fifth resonator 1210 (e.g., a shunt resonator) has a first terminal connected between the first resonator 1204 and the second resonator 1206 and a second terminal connected to a ground potential. A sixth resonator 1212 (e.g., shunt resonator) has a first terminal connected between the second resonator 1206 and the third resonator 1208 and a second terminal connected to a ground potential. Seventh resonator 1214 similarly has a first terminal connected between third resonator 1208 and fourth resonator 1209, and a second terminal connected to a ground potential (e.g., either directly or using additional circuitry, such as an inductor or other connecting circuitry coupled to the ground potential). The microacoustic filter circuit 1200 may, for example, be a band pass circuit having a passband within a selected frequency range (e.g., approximately between 100 MHz and 7 GHZ).

FIG. 12B is a schematic representation of a multiplexer circuit 1250 with multiple filters configured for multi-band communications using antenna node 1280. The filters include filter circuit 1200 from FIG. 12A, including output 1216 and input 1202. Additional filters 1252, 1254, 1256, 1258, 1260, and 1262 are shown, which can be used for corresponding bands of the multi-band communications. Other examples can include multiplexing with any number of filters. Switch 1290 can isolate filters 1260 and 1262 from the remaining filters when the frequency bands associated with filters 1260 and 1262 are not in use. Isolating filters 1260 and 1262 can improve the communication performance of multiplexer circuit 1250 by limiting interference by filters 1260 and 1262 with signals from filters (or filter circuits) 1200-1258 when filters 1260 and 1262 are not in use (e.g., signal loss due to leakage into filters 1260 and 1262 is limited when filters 1260 and 1262 are disconnected by the switch). Other examples may include additional switches to create additional groupings of filters that can be isolated by the switches. Further examples may include no switches, so that all of the filters can be hard-wired at an antenna node as part of the multiplexer circuitry.

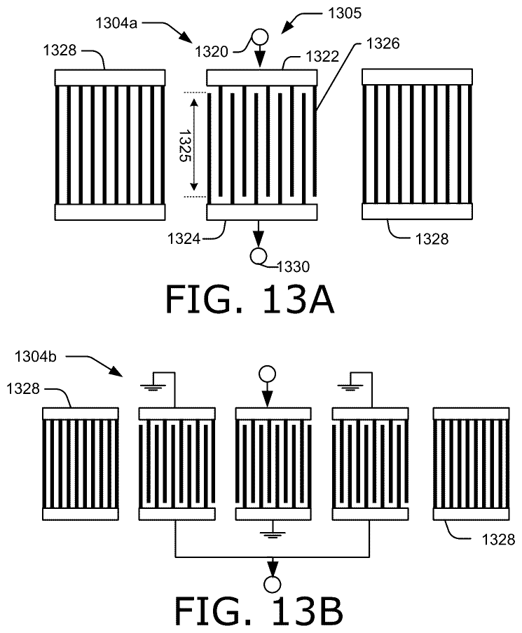

FIG. 13A is a high level representation of a top view of an example of an electrode structure 1304a of a microacoustic device. FIGS. 13A and 13B provide details of reflectors briefly described, but not shown, in FIGS. 4A and 4B. The structures of FIGS. 13A and 13B can be used to implement additional aspects of a membrane-type longitudinal mode resonator as described herein (e.g., the resonator 126.) The electrode structure 1304a has an IDT 1305 that includes a first busbar 1322 (e.g., first conductive segment or rail) electrically connected to a first terminal 1320 and a second busbar 1324 (e.g., second conductive segment or rail) spaced from the first busbar 1322 and connected to a second terminal 1330. A plurality of conductive fingers 1326 are connected to either the first busbar 1322 or the second busbar 1324 in an interdigitated manner. Fingers 1326 connected to the first busbar 1322 extend towards the second busbar 1324 but do not connect to the second busbar 1324 so that there is a small gap between the ends of these fingers 1326 and the second busbar 1324. Likewise, fingers 1326 connected to the second busbar 1324 extend towards the first busbar 1322 but do not connect to the first busbar 1322 so that there is a small gap between the ends of these fingers 1326 and the first busbar 1322.

In the direction along the busbars, there is an overlap region including a central region where a portion of one finger overlaps with a portion of an adjacent finger as illustrated by the central region 1325. This central region 1325 including the overlap may be referred to as the aperture, track, or active region where electric fields are produced between fingers 1326 to cause an acoustic wave to propagate in this region of the piezoelectric layer. The periodicity of the fingers 1326 is referred to as the pitch of the IDT. The pitch may be indicted in various ways. For example, in certain aspects, the pitch may correspond to a magnitude of a distance between fingers in the central region 1325. This distance may be defined, for example, as the distance between center points of each of the fingers (and may be generally measured between a right (or left) edge of one finger and the right (or left) edge of an adjacent finger when the fingers have uniform thickness). In certain aspects, an average of distances between adjacent fingers may be used for the pitch. The frequency at which the piezoelectric material vibrates is a self-resonance (also called a “main-resonance”) frequency of the electrode structure 1304a. The frequency is determined at least in part by the pitch of the IDT 1305 and other properties of the microacoustic device.

The IDT 1305 is arranged between two reflectors 1328 which reflect the acoustic wave back towards the IDT 1305 for the conversion of the acoustic wave into an electrical signal via the IDT 1305 in the configuration shown and to prevent losses (e.g., confine and prevent escaping acoustic waves). Each reflector 1328 has two busbars and a grating structure of conductive fingers that each connect to both busbars. The pitch of the reflector may be similar to or the same as the pitch of the IDT 1305 to reflect acoustic waves in the resonant frequency range. But many configurations are possible.

A variety of electrode structures are possible. FIG. 13A may generally illustrate a one-port configuration. Other port configurations with several ports are also possible as described herein. For example, the electrode structure 1304a may have an input IDT 1305 where each terminal 1320 and 1330 functions as an input. In this case, an adjacent output IDT (not illustrated) that is positioned between the reflectors 1328 and adjacent to the input IDT 1305 may be provided to convert the acoustic wave propagating in the piezoelectric layer to an electrical signal to be provided at output terminals of the output IDT.

FIG. 13B is a diagram of a top view of another example of an electrode structure 1304b of a microacoustic device. In this case, a dual-mode SAW (DMS) electrode structure 1304b is illustrated. The electrode structure 1304b is provided to illustrate the variety of electrode structures that principles described herein may be applied to including the electrode structures 1304a and 1304b of FIGS. 13A and 13B.

It should be appreciated that while a certain number of fingers 1326 are illustrated, the number of actual fingers and lengths and width of the fingers 1326 and busbars may be different in an actual implementation. Such parameters depend on the particular application and desired frequency of the filter. In addition, a SAW filter may include multiple interconnected electrode structures each including multiple IDTs to achieve a desired passband (e.g., multiple interconnected resonators or IDTs to form a desired filter transfer function).

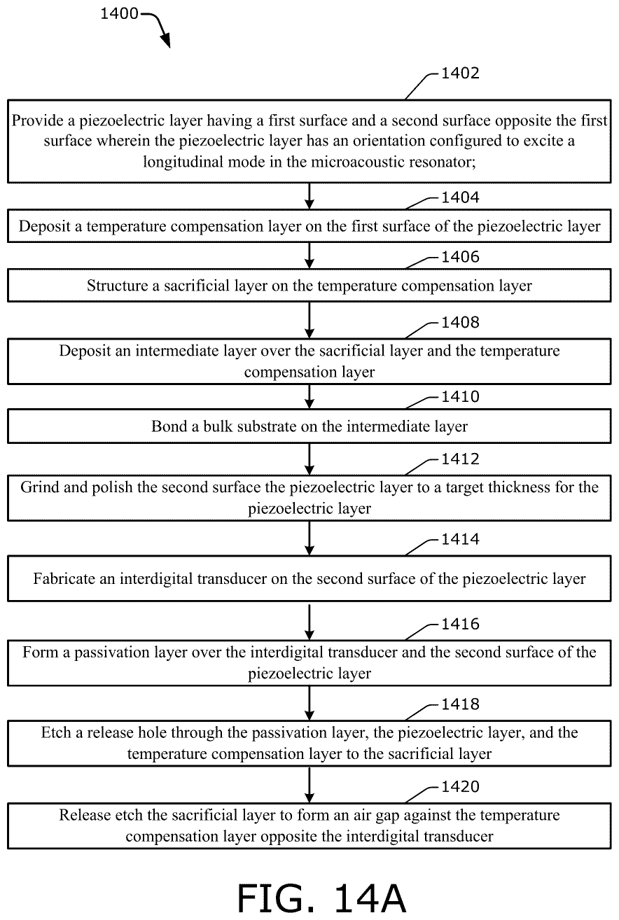

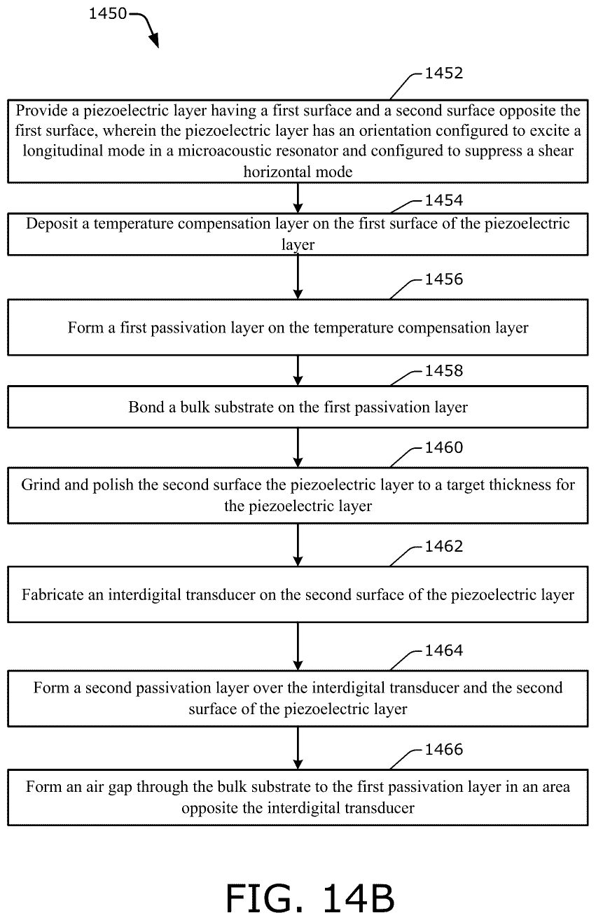

FIG. 14A is a flow diagram illustrating an example process 1400 performed to fabricate a resonator (e.g., the resonator 126) in accordance with aspects described herein. The process 1400 is described in the form of a set of blocks that specify operations that can be performed. However, operations are not necessarily limited to the order shown in FIG. 14A or described herein, for the operations may be implemented in alternative orders or in fully or partially overlapping manners. Also, more, fewer, and/or different operations may be implemented to perform the process 1400, or an alternative process.

The process 1400 includes block 1402, which involves providing a piezoelectric layer having a first surface and a second surface opposite the first surface wherein the piezoelectric layer has an orientation configured to excite a longitudinal mode in the microacoustic resonator.

The process 1400 further includes block 1404, which involves depositing a temperature compensation layer on the first surface of the piezoelectric layer.

The process 1400 further includes block 1406, which involves structuring a sacrificial layer on the temperature compensation layer.

The process 1400 further includes block 1408, which involves depositing an intermediate layer over the sacrificial layer and the temperature compensation layer.

The process 1400 further includes block 1410, which involves bonding a bulk substrate on the intermediate layer.

The process 1400 further includes block 1412, which involves grinding and polishing the second surface the piezoelectric layer to a target thickness for the piezoelectric layer.

The process 1400 further includes block 1414, which involves fabricating an interdigital transducer on the second surface of the piezoelectric layer.

The process 1400 further includes block 1416, which involves forming a passivation layer over the interdigital transducer and the second surface of the piezoelectric layer.

The process 1400 further includes block 1418, which involves etching a release hole through the passivation layer, the piezoelectric layer, and the temperature compensation layer to the sacrificial layer.

The process 1400 further includes block 1420, which involves release etching the sacrificial layer to form an air gap against the temperature compensation layer opposite the interdigital transducer.

FIG. 14B is a flow diagram illustrating an example process 1450 similar to the process 1400 performed to fabricate an alternate implementation of a resonator (e.g., the resonator 126) in accordance with aspects described herein. The process 1450 is described in the form of a set of blocks that specify operations that can be performed. However, operations are not necessarily limited to the order shown in FIG. 14A or described herein, for the operations may be implemented in alternative orders or in fully or partially overlapping manners. Also, more, fewer, and/or different operations may be implemented to perform the process 1450, or an alternative process.

The process 1450 includes block 1452, which includes providing a piezoelectric layer having a first surface and a second surface opposite the first surface, wherein the piezoelectric layer has an orientation configured to excite a longitudinal mode in a microacoustic resonator and configured to suppress a shear horizontal mode.

The process 1450 further includes block 1454, which includes depositing a temperature compensation layer on the first surface of the piezoelectric layer.

The process 1450 further includes block 1456, which includes forming a first passivation layer on the temperature compensation layer.

The process 1450 further includes block 1458, which includes bonding a bulk substrate on the first passivation layer.

The process 1450 further includes block 1460, which includes grinding and polishing the second surface of the piezoelectric layer to a target thickness for the piezoelectric layer.

The process 1450 further includes block 1462, which includes fabricating an interdigital transducer on the second surface of the piezoelectric layer.

The process 1450 further includes block 1464, which includes forming a second passivation layer over the interdigital transducer and the second surface of the piezoelectric layer.

The process 1450 further includes block 1466, which includes forming an air gap through the bulk substrate to the first passivation layer in an area opposite the interdigital transducer.

While the above blocks are illustrated in a particular order, the process 1400 and the process 1450 can include intervening blocks, steps, or operations. Further, blocks to allow fabrication of any structure described herein, or to configure elements of a resonator in accordance with the descriptions herein can be part of implementations of the process 1400 or 1450.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z, or that multiple processors are each tasked with a certain subset of operations X, Y, and Z such that together the multiple processors perform X, Y, and Z, or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

The following is a set of non-limiting aspects in accordance with the details provided herein:

Aspect 1. A microacoustic resonator comprising: a temperature compensation layer comprising a first surface and a second surface opposite the first surface; a piezoelectric layer having a first surface and a second surface opposite the first surface, wherein the piezoelectric layer is disposed on the first surface of the temperature compensation layer with the second surface of the piezoelectric layer facing the first surface of the temperature compensation layer, and wherein the piezoelectric layer has an orientation configured to excite a longitudinal mode; an electrode structure comprising an interdigital transducer disposed on the first surface of the piezoelectric layer; wherein the second surface of the temperature compensation layer faces an air gap.

Aspect 2. The microacoustic resonator of Aspect 1, wherein the piezoelectric layer comprises LiNbO₃ with a crystallographic orientation defined by a set of Euler angles of approximately (λ=90°, μ=90°, θ=40°); and wherein the orientation to excite the longitudinal mode and suppresses a shear horizontal mode comprises a Euler angle orientation of λ=90+/−1.5°, μ=90+/−1.5°, θ=40+/−1.5°).

Aspect 3. The microacoustic resonator of any of Aspects 1 to 2, further comprising a protection layer formed between the temperature compensation layer and the air gap.

Aspect 4. The microacoustic resonator of Aspect 3, wherein the protection layer comprises a Al2O3 layer having a first surface facing the temperature compensation layer, and a second surface exposed to the air gap.

Aspect 5. The microacoustic resonator of any of Aspects 1 to 4, further comprising an intermediate layer disposed on the temperature compensation layer.

Aspect 6. The microacoustic resonator of Aspect 5, wherein the air gap is formed within the intermediate layer using a sacrificial layer.

Aspect 7. The microacoustic resonator of Aspect 6, wherein the intermediate layer comprises a SiO2 layer.

Aspect 8. The microacoustic resonator of Aspect 7, further comprising a bulk substrate bonded to the intermediate layer, the bulk substrate comprising silicon.

Aspect 9. The microacoustic resonator of Aspect 8, wherein the temperature compensation layer is an SiOF layer directly adjacent to the air gap.

Aspect 10. The microacoustic resonator of any of Aspects 1 to 9, wherein the SiOF layer has a thickness between 95 nanometers (nm) and 105 nm

Aspect 11. The microacoustic resonator of any of Aspects 1 to 10, further comprising a passivation layer formed over the electrode structure and the first surface of the piezoelectric layer.

Aspect 12. The microacoustic resonator of Aspect 11, wherein the passivation layer comprises an Si3N4 layer.

Aspect 13. The microacoustic resonator of any of Aspects 1 to 12 further comprising a dielectric cover formed over the electrode structure and the first surface of the piezoelectric layer.

Aspect 14. The microacoustic resonator of Aspect 13, wherein the dielectric cover comprises an SiO2 layer.

Aspect 15. The microacoustic resonator of Aspect 14, further comprising a passivation layer disposed on the dielectric cover; wherein the dielectric cover and the passivation layer are configured to suppress a low velocity Rayleigh mode.

Aspect 16. The microacoustic resonator of any of Aspects 1 to 15, further comprising a bulk substrate attached to the temperature compensation layer via a protective layer.

Aspect 17. The microacoustic resonator of Aspect 16, wherein the air gap is formed via Bosch fabrication of the air gap through the bulk substrate to the protective layer opposite the electrode structure.

Aspect 18. The microacoustic resonator of any of Aspects 1 to 17, wherein the air gap is formed within a bulk substrate supporting the temperature compensation layer; and wherein a boundary of an active region is aligned with edges of the interdigital transducer and edges of the air gap.

Aspect 19. The microacoustic resonator of Aspect 18, further comprising a protection layer disposed between the bulk substrate and the temperature compensation layer.

Aspect 20. The microacoustic resonator of any of Aspects 1 to 19, wherein the microacoustic resonator is disposed in a wireless communication filter for a communication frequency between 2.5 gigahertz (GHz) and 6 GHz.

Aspect 21. A microacoustic resonator comprising: a dielectric layer comprising a first surface and a second surface opposite the first surface; a piezoelectric layer having a first surface and a second surface opposite the first surface, wherein the piezoelectric layer is disposed on the first surface of the dielectric layer with the second surface of the piezoelectric layer facing the first surface of the dielectric layer, and wherein the piezoelectric layer is LiNbO3 having a crystallographic orientation defined by a set of Euler angles of λ=90+/−1.5°, μ=90+/−1.5°, θ=40+/−1.5°; and an electrode structure comprising an interdigital transducer disposed on the first surface of the piezoelectric layer, wherein the second surface of the dielectric layer faces an air gap.

Aspect 22. The microacoustic resonator of Aspect 21, wherein the air gap is formed in a bulk substrate; and wherein edges of the air gap are aligned with a border of an active region of the electrode structure.

Aspect 23. The microacoustic resonator of any of Aspects 21 to 22, further comprising a protection layer having a first surface facing the bulk substrate and the air gap, and a second surface opposite the first surface, wherein the second surface faces the dielectric layer.

Aspect 24. The microacoustic resonator of any of Aspects 21 to 23, further comprising: a dielectric cover layer disposed on the piezoelectric layer; a passivation layer disposed on the dielectric cover layer.

Aspect 25. A method of fabricating an microacoustic resonator, the method comprising: providing a piezoelectric layer having a first surface and a second surface opposite the first surface wherein the piezoelectric layer has an orientation configured to excite a longitudinal mode in the microacoustic resonator; depositing a temperature compensation layer on the first surface of the piezoelectric layer; structuring a sacrificial layer on the temperature compensation layer; depositing an intermediate layer over the sacrificial layer and the temperature compensation layer; bonding a bulk substrate on the intermediate layer; grinding and polishing the second surface the piezoelectric layer to a target thickness for the piezoelectric layer; fabricating an interdigital transducer on the second surface of the piezoelectric layer; forming a passivation layer over the interdigital transducer and the second surface of the piezoelectric layer; etching a release hole through the passivation layer, the piezoelectric layer, and the temperature compensation layer to the sacrificial layer; and release etching the sacrificial layer to form an air gap against the temperature compensation layer opposite the interdigital transducer.

Aspect 26. The method of Aspect 25, further comprising etching a first etch stop layer following deposition of the temperature compensation layer; and depositing a second stop layer after structuring the sacrificial layer.

Aspect 27. The method of Aspect 26, further comprising sealing the release hole after release etching the sacrificial layer to enclose the air gap.

Aspect 28. A method comprising: providing a piezoelectric layer having a first surface and a second surface opposite the first surface, wherein the piezoelectric layer has an orientation configured to excite a longitudinal mode in a microacoustic resonator and configured to suppress a shear horizontal mode; depositing a temperature compensation layer on the first surface of the piezoelectric layer; forming a first passivation layer on the temperature compensation layer; bonding a bulk substrate on the first passivation layer; grinding and polishing the second surface of the piezoelectric layer to a target thickness for the piezoelectric layer; fabricating an interdigital transducer on the second surface of the piezoelectric layer; forming a second passivation layer over the interdigital transducer and the second surface of the piezoelectric layer; and forming an air gap through the bulk substrate to the first passivation layer in an area opposite the interdigital transducer.

Aspect 29. The method of Aspect 28, wherein the air gap is formed using a Bosch process to form a complete backside opening opposite the interdigital transducer.

Aspect 30. The method of any of Aspects 28 to 29, wherein the piezoelectric layer comprises LiNbO3 with a crystallographic orientation defined by a set of Euler angles of approximately (λ=90°, μ=90°, θ=40°); and wherein the orientation to excite the longitudinal mode and suppresses the shear horizontal mode comprises a Euler angle orientation of λ=90+/−1.5°, μ=90+/−1.5°, θ=40+/−1.5°.

What is claimed is:

1. A microacoustic resonator comprising:
a temperature compensation layer comprising a first surface and a second surface opposite the first surface;
a piezoelectric layer having a first surface and a second surface opposite the first surface, wherein the piezoelectric layer is disposed on the first surface of the temperature compensation layer with the second surface of the piezoelectric layer facing the first surface of the temperature compensation layer, and wherein the piezoelectric layer has an orientation configured to excite a longitudinal mode;
an electrode structure comprising an interdigital transducer disposed on the first surface of the piezoelectric layer;
wherein the second surface of the temperature compensation layer faces an air gap.

2. The microacoustic resonator of claim 1, wherein the piezoelectric layer comprises LiNbO₃ with a crystallographic orientation defined by a set of Euler angles of approximately (λ=90°, μ=90°, θ=40°); and
wherein the orientation to excite the longitudinal mode and suppresses a shear horizontal mode comprises a Euler angle orientation of λ=90+/−1.5°, μ=90+/−1.5°, θ=40+/−1.5°.

3. The microacoustic resonator of claim 1, wherein the temperature compensation layer is an SiOF layer directly adjacent to the air gap.

4. The microacoustic resonator of claim 3, wherein the SiOF layer has a thickness between 95 nanometers (nm) and 105 nm.

5. The microacoustic resonator of claim 2, further comprising a protection layer formed between the temperature compensation layer and the air gap.

6. The microacoustic resonator of claim 5, wherein the protection layer comprises a Al₂O₃ layer having a first surface facing the temperature compensation layer, and a second surface exposed to the air gap.

7. The microacoustic resonator of claim 1, further comprising a passivation layer formed over the electrode structure and the first surface of the piezoelectric layer.

8. The microacoustic resonator of claim 7, wherein the passivation layer comprises an Si₃N₄ layer.

9. The microacoustic resonator of claim 1 further comprising a dielectric cover formed over the electrode structure and the first surface of the piezoelectric layer.

10. The microacoustic resonator of claim 9, wherein the dielectric cover comprises an SiO₂ layer.

11. The microacoustic resonator of claim 10, further comprising a passivation layer disposed on the dielectric cover;
wherein the dielectric cover and the passivation layer are configured to suppress a low velocity Rayleigh mode.

12. The microacoustic resonator of claim 2, further comprising an intermediate layer disposed on the temperature compensation layer.

13. The microacoustic resonator of claim 12, wherein the air gap is formed within the intermediate layer using a sacrificial layer.

14. The microacoustic resonator of claim 13, wherein the intermediate layer comprises a SiO₂ layer.

15. The microacoustic resonator of claim 14, further comprising a bulk substrate bonded to the intermediate layer, the bulk substrate comprising silicon.

16. The microacoustic resonator of claim 1, further comprising a bulk substrate attached to the temperature compensation layer via a protective layer.

17. The microacoustic resonator of claim 16, wherein the air gap is formed via Bosch fabrication of the air gap through the bulk substrate to the protective layer opposite the electrode structure.

18. The microacoustic resonator of claim 1, wherein the air gap is formed within a bulk substrate supporting the temperature compensation layer; and
wherein a boundary of an active region is aligned with edges of the interdigital transducer and edges of the air gap.

19. The microacoustic resonator of claim 18, further comprising a protection layer disposed between the bulk substrate and the temperature compensation layer.

20. The microacoustic resonator of claim 1, wherein the microacoustic resonator is disposed in a wireless communication filter for a communication frequency between 2.5 gigahertz (GHz) and 6 GHz.

21. A microacoustic resonator comprising:
a dielectric layer comprising a first surface and a second surface opposite the first surface;
a piezoelectric layer having a first surface and a second surface opposite the first surface, wherein the piezoelectric layer is disposed on the first surface of the dielectric layer with the second surface of the piezoelectric layer facing the first surface of the dielectric layer, and wherein the piezoelectric layer is LiNbO₃ having a crystallographic orientation defined by a set of Euler angles of λ=90+/−1.5°, μ=90+/−1.5°, θ=40+/−1.5°; and
an electrode structure comprising an interdigital transducer disposed on the first surface of the piezoelectric layer,
wherein the second surface of the dielectric layer faces an air gap.

22. The microacoustic resonator of claim 21, wherein the air gap is formed in a bulk substrate; and
wherein edges of the air gap are aligned with a border of an active region of the electrode structure.

23. The microacoustic resonator of claim 22, further comprising a protection layer having a first surface facing the bulk substrate and the air gap, and a second surface opposite the first surface, wherein the second surface faces the dielectric layer.

24. The microacoustic resonator of claim 21, further comprising:
a dielectric cover layer disposed on the piezoelectric layer;
a passivation layer disposed on the dielectric cover layer.

25. A method of fabricating an microacoustic resonator, the method comprising:
providing a piezoelectric layer having a first surface and a second surface opposite the first surface wherein the piezoelectric layer has an orientation configured to excite a longitudinal mode in the microacoustic resonator;
depositing a temperature compensation layer on the first surface of the piezoelectric layer;
structuring a sacrificial layer on the temperature compensation layer;
depositing an intermediate layer over the sacrificial layer and the temperature compensation layer;
bonding a bulk substrate on the intermediate layer;
grinding and polishing the second surface the piezoelectric layer to a target thickness for the piezoelectric layer;
fabricating an interdigital transducer on the second surface of the piezoelectric layer;
forming a passivation layer over the interdigital transducer and the second surface of the piezoelectric layer;
etching a release hole through the passivation layer, the piezoelectric layer, and the temperature compensation layer to the sacrificial layer; and
release etching the sacrificial layer to form an air gap against the temperature compensation layer opposite the interdigital transducer.

26. The method of claim 25, further comprising etching a first etch stop layer following deposition of the temperature compensation layer; and
depositing a second stop layer after structuring the sacrificial layer.

27. The method of claim 25, further comprising sealing the release hole after release etching the sacrificial layer to enclose the air gap.

28. A method comprising:
providing a piezoelectric layer having a first surface and a second surface opposite the first surface, wherein the piezoelectric layer has an orientation configured to excite a longitudinal mode in a microacoustic resonator and configured to suppress a shear horizontal mode;
depositing a temperature compensation layer on the first surface of the piezoelectric layer;
forming a first passivation layer on the temperature compensation layer;
bonding a bulk substrate on the first passivation layer;
grinding and polishing the second surface of the piezoelectric layer to a target thickness for the piezoelectric layer;
fabricating an interdigital transducer on the second surface of the piezoelectric layer;
forming a second passivation layer over the interdigital transducer and the second surface of the piezoelectric layer; and
forming an air gap through the bulk substrate to the first passivation layer in an area opposite the interdigital transducer.

29. The method of claim 28, wherein the air gap is formed using a Bosch process to form a complete backside opening opposite the interdigital transducer.

30. The method of claim 28, wherein the piezoelectric layer comprises LiNbO₃ with a crystallographic orientation defined by a set of Euler angles of approximately (λ=90°, μ=90°, θ=40°); and
wherein the orientation to excite the longitudinal mode and suppresses the shear horizontal mode comprises a Euler angle orientation of λ=90+/−1.5°, μ=90+/−1.5°, θ=40+/−1.5°.
